(19) United States
(12) Patent Application Publication
(10) Pub. No.: US 2007/0166950 A1
(43) Pub. Date: Jul. 19, 2007

(54) Semiconductor device fabrication method for improving capability for burying a conductive film in the trenches of trench gates

(75) Inventor: Masahiko Ohuchi, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/653,846

(22) Filed: Jan. 17, 2007

(30) Foreign Application Priority Data
Jan. 18, 2006 (JP) 2006-009831

(51) Int. Cl. H01L 21/76

(52) U.S. Cl. 438/424

(57) ABSTRACT

A method of fabricating a semiconductor device includes: forming element isolation parts that enclose a plurality of active regions in which transistors are formed and that have profiles perpendicular to the substrate surface that are reverse tapered shapes; after forming the element isolation parts, forming an oxidation-resistant insulation mask that covers the regions of the sources and drains of the transistors in the plurality of active regions; subjecting the substrate to anisotropic etching from above the oxidation-resistant insulation mask; forming trenches for trench gates in the active regions; removing the natural oxidation film that has formed on the substrate surface of the trenches; thereafter heating in a hydrogen atmosphere; after the heat treatment, removing the oxidation-resistant insulation mask; after removing the oxidation-resistant insulation mask, cleaning with an ammonium-hydrogen peroxide mixture; and after cleaning, forming a gate oxide film on the substrate surface of the trenches by a thermal oxidation method.

This application is based upon and claims the benefit of priority from Japanese Patent Application No. 2006-9831 filed on Jan. 18, 2006, the content of which is incorporated by reference.

### BACKGROUND OF THE INVENTION

1. Field of the Invention

The present invention relates to a method for fabricating a semiconductor device that is provided with MOS (Metal Oxide Semiconductor) transistors having trench gates as gate electrodes.

2. Description of the Related Art

With the technological developments of recent years, semiconductor devices have been put into practical use that are provided with “trench gates” in which gate electrodes are buried in trenches formed on a substrate surface (Refer to JP-A-2005-142265. This document is hereinbelow referred to as Document 1). In particular, trench gates are used for easing the electrical field applied to gate electrodes in transistors for selecting memory cells of DRAM (Dynamic Random Access Memory), which are one type of memory elements. This use of trench gates can improve the refresh characteristic.

FIG. 1A and FIG. 1B are a plan view and a sectional view showing an example of the configuration of DRAM that uses trench gates. FIG. 1A shows a plan of a memory cell array, and FIG. 1B shows a sectional view taken along line A-A′ of FIG. 1A.

The memory cell array of silicon substrate 100 is provided with a plurality of each of: active regions that include the source-drains and channel generation points of selection transistors, and gate electrodes that serve as word lines. In the following explanation, the impurity diffusion regions that are to be source-drains will be referred to as simply “diffusion regions.”

As shown in FIG. 1A, a plurality of active regions intersect with each of a plurality of gate electrodes 110a, 110b, 110d, and 110e that are aligned in parallel rows at a fixed distance. The active regions in which selection transistors are formed are in the shape of rectangles having rounded corner portions and intersect diagonally with gate electrodes. STI (Shallow Trench Isolation) is used in the element isolation parts for isolating the active regions. STI is a structure in which a silicon oxide film is buried in grooves.

Focusing on the active region at the upper right of FIG. 1A, a selection transistor that includes diffusion regions 114a and 114c and gate electrode 110a and a selection-transistor that includes diffusion regions 114b and 114c and gate electrode 110b are provided. Diffusion region 114c is shared by these two selection transistors and is connected to bit lines (not shown) by way of a plug that does not appear in the figure. In addition, each of diffusion regions 114a and 114b are connected to capacitors (not shown) for accumulating data by way of plugs that are not shown in the figure. Gate electrode 110a has the structure of trench gate 120 in the active region. The other gate electrodes 110b, 110d, and 110e are similar.

As shown in FIG. 1B, in trench gate 120, a polycrystalline silicon film into which impurity has been introduced (hereinbelow referred to as “doped polysilicon film”) 108 is buried in the trenches. Gate electrodes 110 are structures in which W (tungsten)/WN(tungsten nitride) film 106 is formed over doped polysilicon film 108. STI 104 is arranged between trench gates 120 in which doped polysilicon film 108 has been buried. In addition, gate oxide film 102 is formed between gate electrode 110 and silicon substrate 100. Silicon nitride film (Si₃N₄ film) 112 is provided on gate electrodes 110 as a protection film.

Problems resulting from trenches are disclosed in K. Okonogi et al. in “Lattice Strain Design in W/WN/Poly-Si gate DRAM for Improving Data Retention Time,” IMED, 2004. This document is hereinbelow referred to as Document 2.

In the above-described technology, projecting silicon burrs 90 are formed at the points of intersection between trench gates and STI as shown in FIG. 1B. The reasons for the occurrence of silicon burrs 90 are next described.

FIG. 2 is a plan view for explaining the step of forming trenches for gates. FIG. 3A shows a sectional view along line A-A′ of FIG. 2, and FIG. 3B shows a sectional view taken along line B-B′ of FIG. 2. In FIG. 2, the upper and lower portions of oxidation-resistant insulation mask 116 have been cut midway, and the upper and lower sides are omitted from the figure. Part of oxidation-resistant insulation mask 116 of diffusion region 114 shown on the left side of FIG. 2 has also been omitted from the figure.

As shown in FIG. 2, when forming trenches for gates, the diffusion regions are covered by oxidation-resistant insulation mask 116. Anisotropic etching is then carried out to etch the points of trench gate formation region 118 of silicon substrate 100. STI 104 have a reverse-tapered shape with the upper portion larger than the lower portion, and STI 104 therefore act as overhangs that cover silicon substrate 100 during anisotropic etching, whereby silicon remains along the side walls of STI 104. These remnants become silicon burrs 90.

On the other hand, making STI 104 vertical instead of a reverse-tapered shape causes problems that have adverse effects upon the gate characteristics such as (1) the embedding capabilities are degraded, causing the occurrence of STI voids and defects that are difficult to repair; and (2) the diffusion layer undergoes stress from the embedding film, causing degradation of the refresh characteristics (see Document 2). In addition, from the standpoint of the embedding capabilities of the silicon oxide film, STI 104 preferably have a reverse-tapered shape. The problem therefore arises that the occurrence of silicon burrs 90 cannot be prevented.

Modification of the etching conditions for the trenches for gates to test whether silicon burrs 90 can be reduced produced results such as the bowing of the trench sidewalls or the occurrence of deep depressions in the STI. Each of these problems is explained below.

FIG. 4B is a sectional view showing a case in which bowing 122 occurs in the trench side walls, and shows a section along line B-B′ in FIG. 2. The degradation of the shape of the trench side walls in this case causes the problems of interference with the desired source-drain formation and the inability to obtain the desired gate threshold voltage Vt.

FIG. 5B is a sectional view showing a case in which deep depressions 124 occur in STI 104, and shows a section taken along line B-B′ of FIG. 2. In this case, fine irregularities are formed across the substrate. This results in the occurrence of voids when forming the gate electrode material in the next step, which further results in the problem of non-resolution in lithography in the following step. These fine irregularities further lead to the problem of etching residue when carrying out etching to form the gate electrode pattern.

### SUMMARY OF THE INVENTION

It is an object of the present invention to provide a method of fabricating a semiconductor device in which the ability to bury a conductive film within the trenches of trench gates is improved.

According to the present invention, a method of fabricating a semiconductor device, the semiconductor device having trench gates as the gate electrodes of transistors; comprises the steps of: forming on a substrate element isolation parts that enclose a plurality of active regions in which the transistors are formed, wherein profiles of the element isolation parts in a perpendicular direction with respect to a substrate surface are reverse-tapered shapes; after forming the element isolation parts, forming an oxidation-resistant insulation mask that covers the regions of sources and drains of the transistors in the plurality of active regions; subjecting the substrate to anisotropic etching from above the oxidation-resistant insulation mask to form trenches for the trench gates in the active regions; removing the natural oxidation film that has formed on a substrate surface of the trenches; after removing the natural oxidation film, carrying out an annealing process by performing a heat treatment in a hydrogen atmosphere; after the annealing process, removing the oxidation-resistant insulation mask; after removing the oxidation-resistant insulation mask, carrying out a cleaning process by cleaning with a mixture containing ammonium-hydrogen peroxide; and after the cleaning process, forming a gate oxide film on a substrate surface of the trenches by a thermal oxidation method.

When etching the substrate to form gate trenches, the upper portions of element isolation parts that have a reverse-tapered shape act as overhangs and thus cause the formation of burrs formed by the substrate material. In the present invention, however, a heat treatment in a hydrogen atmosphere and cleaning in an ammonium-hydrogen peroxide mixture reduces the height of these burrs.

In the present invention, the burrs that were formed on the side walls of element isolation parts by etching of trench formations are removed by an annealing treatment in a hydrogen atmosphere and cleaning in an ammonium-hydrogen peroxide mixture, and as a result, the ability to embed a conductive film in the trenches for gates is improved. In addition, the oxide film of the element isolation parts is not etched despite hydrogen atmosphere annealing, and as a result, large unevenness is not produced on the substrate surface, making this method advantageous for microfabrication. Further, migration brought about by the heat of the hydrogen atmosphere annealing process causes semiconductor atoms of the substrate material to move in the direction of energy stability, whereby crystal defects are restored and a superior gate oxide film is formed.

The above and other objects, features and advantages of the present invention will become apparent from the following description with reference to the accompanying drawings which illustrate examples of the present invention.

### BRIEF DESCRIPTION OF THE DRAWINGS

FIG. 1A is a plan view and FIG. 1B is a sectional view showing an example of the configuration of a semiconductor device;

FIG. 2 is a plan view for explaining the formation steps of trenches for gates;

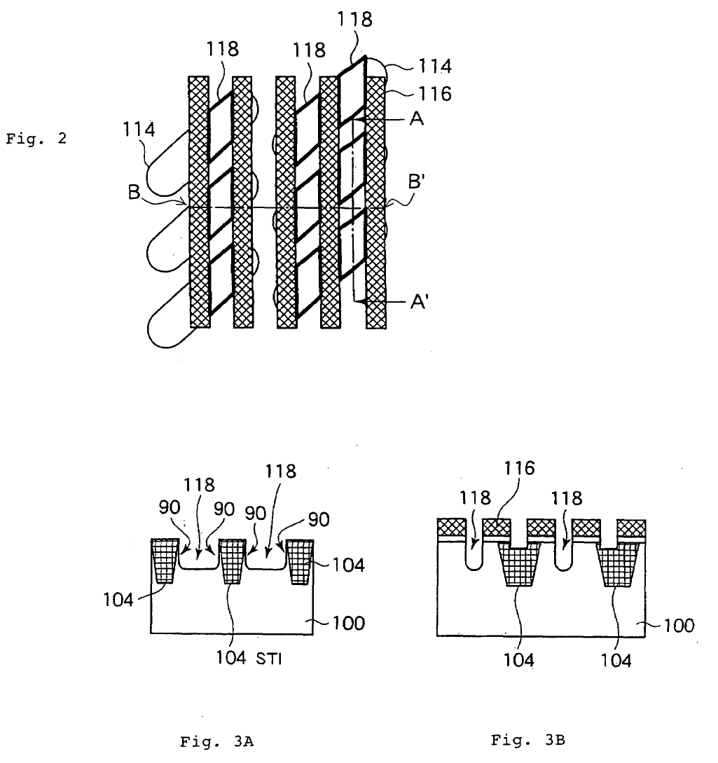

FIG. 3A and FIG. 3B are sectional views for explaining the formation steps of trenches for gates;

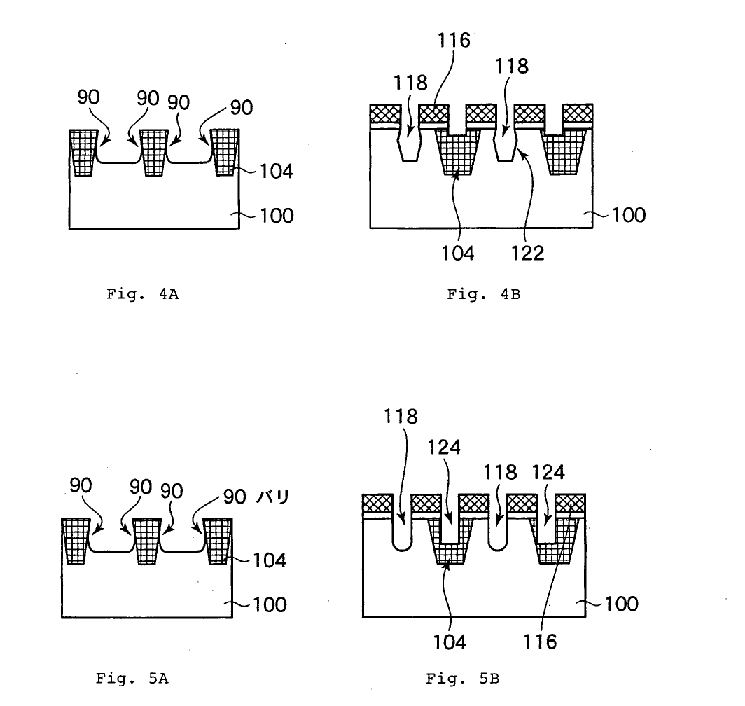

FIG. 4A and FIG. 4B are sectional views showing a case in which bowing occurs in trench side walls;

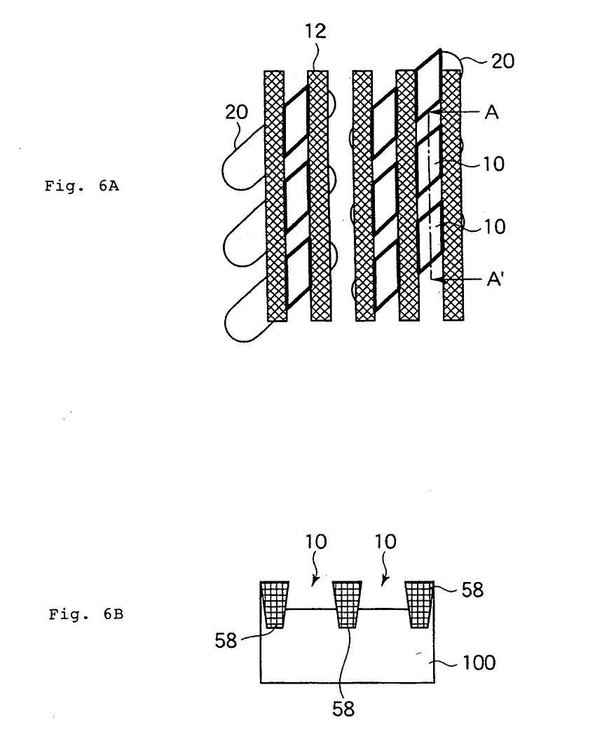

FIG. 5A and FIG. 5B are sectional views showing a case in which deep depressions occur in STI;

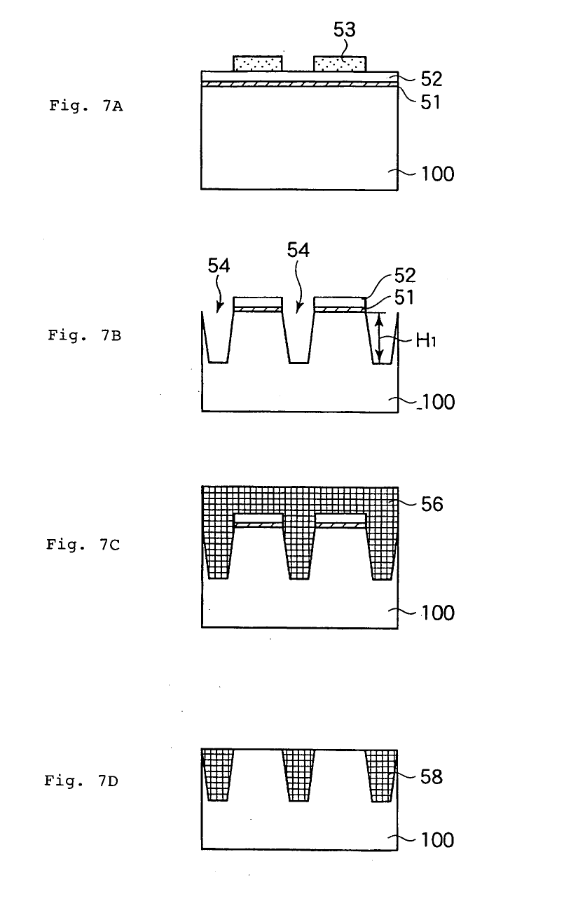

FIG. 6A is a plan view and FIG. 6B is a sectional view showing an example of the configuration of a semiconductor device of a first working example; and

FIG. 7A to FIG. 7H are sectional views showing the method of fabricating the semiconductor device of the first working example

### DETAILED DESCRIPTION OF THE PREFERRED EMBODIMENTS

The method of fabricating a semiconductor device of the present invention includes a step of annealing in a hydrogen atmosphere after forming trenches-for gates on a substrate, and a step of cleaning by means of an ammonium-hydrogen peroxide mixture.

### FIRST WORKING EXAMPLE

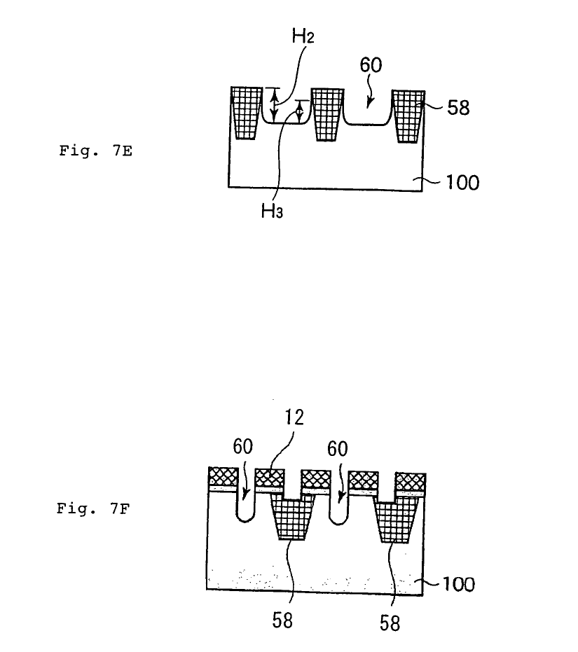

Explanation next regards the configuration of the semiconductor device of the present working example. FIG. 6A is a plan view and FIG. 6B is a sectional view showing an example of the configuration of the semiconductor device of the present working example. FIG. 6A is a plan view of the layout of a memory cell array after formation of trenches for gates, and FIG. 6B is a sectional view taken along line A-A′ of FIG. 6A.

FIG. 6A shows the state after diffusion region 20 has been covered by oxidation-resistant insulation mask 12 and grooves have been formed in trench gate formation region 10. In the present working example, silicon burrs are not formed in trench gate formation region 10, as shown in FIG. 6B. Explanation next regards the method of fabricating the semiconductor device of the present working example.

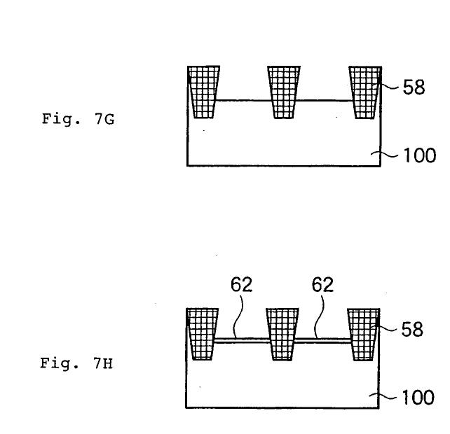

FIGS. 7A to 7H are sectional views showing the method of fabricating the semiconductor device of the present working example. FIG. 7F is a sectional view taken along line B-B′ of FIG. 6A, and the other figures are all sectional views taken along line A-A′ of FIG. 6A.

Silicon dioxide film (SiO₂ film) 51 is formed as an insulating film by a thermal oxidation method on silicon substrate 100. Next, silicon nitride film (Si₃N₄ film) 52 that is to serve as a hard mask is formed on silicon dioxide film 51 by a CVD (Chemical Vapor Deposition) method. A lithography method is next used to form photoresist (PR) 53 having an element isolation pattern on silicon nitride film 52 (FIG. 7A).

After etching of silicon nitride film 52 and silicon dioxide film 51 is simultaneously carried out, using PR 53 as a mask, PR 53 is removed by acid stripping by means of SPM (a sulfuric-acid hydrogen-peroxide mixture) and APM (an ammonium-hydrogen peroxide mixture). Isolation trenches 54 are formed by carrying out etching of silicon substrate 100 using the silicon nitride film 52 as a hard mask (FIG.7B). At this time, taking embedding capabilities into consideration, the taper angle of the trenches is set to 82°-87° in the most concentrated regions (when the size between STIs is on the order of 100 nm), and the trench depth H₁ is set to 200-250 nm. The shape of these isolation trenches 54 determines the shape of STI 58 shown in FIG. 6B. Further, this taper angle is the angle formed by the side walls of the trenches and the horizontal plane and extends in a taper shape in order from the trench bottoms of silicon substrate 100.

Next, as shown in FIG. 7C, silicon dioxide film 56 is embedded in isolation trenches 54 by a CVD method such as HDP (High-Density Plasma). Silicon dioxide film 56 and silicon nitride film 52 are further polished by CMP (Chemical and Mechanical Polishing) until the upper surface of silicon substrate 100 is exposed (FIG. 7D). Etching by a wet process may also be used in place of CMP. Further, in an MOS device that does not use trench gates, after the step shown in FIG. 7D, the process advances to a step for forming an oxide film by thermal oxidation, this oxide film being for a gate insulation film.

After the step shown in FIG. 7D in the present working example, a silicon nitride film (Si₃N₄) (not shown) is formed for forming a hard mask for processing the gate trenches. PR (photoresist) in a line pattern is next formed on the silicon nitride film by a lithography method. Oxidation-resistant insulation mask 12 is further formed as shown in FIG. 6A by carrying out dry etching of the silicon nitride film using the PR as a mask.

After removing the PR, anisotropic etching is carried out for forming gate trenches 60 using oxidation-resistant insulation mask 12 shown in FIG. 6A as a hard mask. FIG. 7E shows the section taken along line A-A′ of FIG. 6A after etching, and FIG. 7F shows the section along line B-B′ of FIG. 6A after etching.

In contrast to the etching conditions in the step of FIG. 7B, this etching has conditions such that the trenches have a vertical shape. The trench depth H₂ of the gate trenches is approximately 150-200 nm in the present working example, this depth being shallower than trench depth H₁ of the isolation trenches.

Explanation next regards an example of an etching system for carrying out this etching and the conditions of this etching. An inductive coupled plasma (ICP) source-etching system is used as the etching system, and the etching conditions include the following three steps:

| | |
|---|---|
| Step 1 | |
| Gas: | CF₄ = 100 sccm |
| Pressure: | 4 mTorr |
| Source power: | 300 W |
| Bias power: | 100 W |
| Stage temperature: | 20° C. |
| Etching time: | 10 seconds |
| Step 2 | |
| Gas: | HBr/SF₆ = 150/30 sccm |
| Pressure: | 6 mTorr |
| Source power: | 800 W |
| Bias power: | 100 W |
| Stage temperature: | 20° C. |
| Etching time: | 20 seconds |
| Step 3 | |
| Gas: | CF₄/Ar/O₂ = 200/200/40 sccm |
| Pressure: | 10 mTorr |
| Source power: | 1000 W |
| Bias power: | 0 W |
| Stage temperature: | 20° C. |
| Etching time: | 20 seconds |

In addition, 1 Torr = 133.3 Pa.

After etching having the above three steps has been carried out, deposits resulting from etching are sufficiently removed by acid, for example, by stripping by means of SPM and APM. As shown in FIG. 7E, silicon burrs at this time are large, as in the prior art. Although slight differences occur due to the etching conditions at the time of forming isolation trenches or the mask pattern, height H₃ of the silicon burrs is 20-50 nm.

After the natural oxidation film of the silicon surface is removed by a solution containing hydrofluoric acid, an annealing process in a hydrogen atmosphere is carried out to remove the silicon burrs. As annealing conditions that are more effective for removing silicon burrs, a high-vacuum state is realized in which pressure is 30 Torr or less, and the temperature is set to at least 750° C. but not greater than 900° C. When the temperature is lower than 750° C. or higher than 900° C., the silicon burr removal effect is reduced compared to a case in which the temperature range is 750°-900° C.

A RTA(Rapid Thermal Annealer) is used as the annealing system. A RTA is used because this system is capable of raising and lowering temperature more rapidly than a furnace annealer of a batch-type and therefore allows closer control. An actual example of the annealing conditions is shown below for a case in which a RTA is used.

| | |
|---|---|
| Stage temperature: | 800° C. |
| Pressure: | 15 Torr |
| Gas: | H₂ = 30 slm |
| Processing time: | 60 seconds |

By implementing this type of hydrogen atmosphere annealing process, a shape is obtained that lacks silicon burrs, as shown in FIG. 7G. Even if the silicon burrs are not completely removed, the height H₃ of the silicon burrs is preferably 10 nm or less.

Oxidation-resistant insulation mask 12 is removed by H₃PO₄ at 150 to 200° C., following which a silicon surface layer into which hydrogen has been introduced is removed by a cleaning process such as APM. A thin layer of the silicon surface layer is cut such that the hydrogen that has been introduced into the silicon surface layer is also removed. Even when the silicon burrs are not sufficiently eliminated by the hydrogen atmosphere annealing process, this process of removing the silicon surface layer has the effect of reducing the height of the silicon burrs. This process of removing the silicon surface layer has the additional effect of eliminating the etch-damage layer that results from the dry etching for forming trenches.

Next, as shown in FIG. 7H, gate oxide film 62 is formed on silicon substrate 100 by a thermal oxidation method. Hydrogen was removed from the silicon surface layer as described hereinabove because the use of an oxide film containing a large amount of hydrogen as a gate oxide film raises the potential for problems such as leakage and deterioration of dielectric breakdown voltage. In the case of the present working example, moreover, the migration resulting from the heat of the hydrogen atmosphere annealing process causes silicon atoms to move in the direction of energy stability, and crystal defects caused by etch-damage are thus restored. As a result, gate oxide film 62 becomes a more superior insulation film.

A doped polysilicon film (not shown) is next buried as a conductive film in gate trenches 60, and the upper surface of the doped polysilicon film is then planarized by CMP or dry etch-back. A metal film (not shown) such as W/WN is then formed as a conductive film on doped polysilicon film. A hard mask realized by an insulation film such as a silicon nitride film (Si₃N₄ film) is further formed on the metal film, and etching is then carried out from above the hard mask to form gate electrodes from the conductive film. Subsequent steps are the same as the prior art, and detailed explanation is therefore here omitted.

In the method of fabricating a semiconductor device of the present working example, gate trenches are formed in active regions of memory cells, following which a hydrogen annealing process is carried out for a fixed time interval and APM cleaning is carried out such that projecting silicon burrs do not remain at the intersections with STI. In addition, hydrogen annealing is carried out under the conditions of a prescribed pressure or less and within a prescribed temperature range to further augment the silicon burr removal effect. Removing silicon burrs from within the gate trenches improves the capability to embed a conductive film compared to the prior art.

In addition, because the silicon oxide film of the STI is not etched, the hydrogen atmosphere annealing does not produce great differences in level due to unevenness on the substrate, and is therefore advantageous for microfabrication.

After the step of hydrogen atmosphere annealing, an internal oxidation film which is formed by oxidizing the silicon surface layer in the trench gate formation region, may be formed, following which the internal oxidation film may be removed and the above-described APM cleaning process carried out. By removing the internal oxidation film, hydrogen or sites of etch-damage caused by dry etching that are contained in the silicon surface layer are removed together. In this case, the effect of removing hydrogen and etch-damage is greater than a case in which only the APM cleaning process is carried out. Still further, even when some silicon burrs remain after the hydrogen atmosphere annealing step, the silicon burrs all become oxides, and the silicon burrs can therefore be reliably removed.

Still further, the material of oxidation-resistant insulation mask 12 is not limited to a silicon nitride film (Si₃N₄ film) and need only be a film having high etching selectivity with respect to the substrate material and may also be a SiCN film formed by a plasma CVD method.

### SECOND WORKING EXAMPLE

This working example is directed toward avoiding etching having high step when forming gate electrodes. Explanation next regards this method. Elements that are the same as the first working example are identified by the same reference numerals.

As shown in FIG. 6A, oxidation-resistant insulation mask 12 is formed as the etching mask of gate trenches, following which side walls composed of silicon nitride film (Si₃N₄ film) are formed on the side walls of oxidation-resistant insulation mask 12. As the method of forming the side walls, silicon nitride film is formed over the entire surface, following which this film is subjected to anisotropic etching. In this way, the width of trench gate formation region 10 in the right-left direction of FIG. 6A becomes smaller than in the case of the first working example. Processing from the etching step for forming gate trenches to the step for forming gate oxidation film is subsequently carried out as in the first working example.

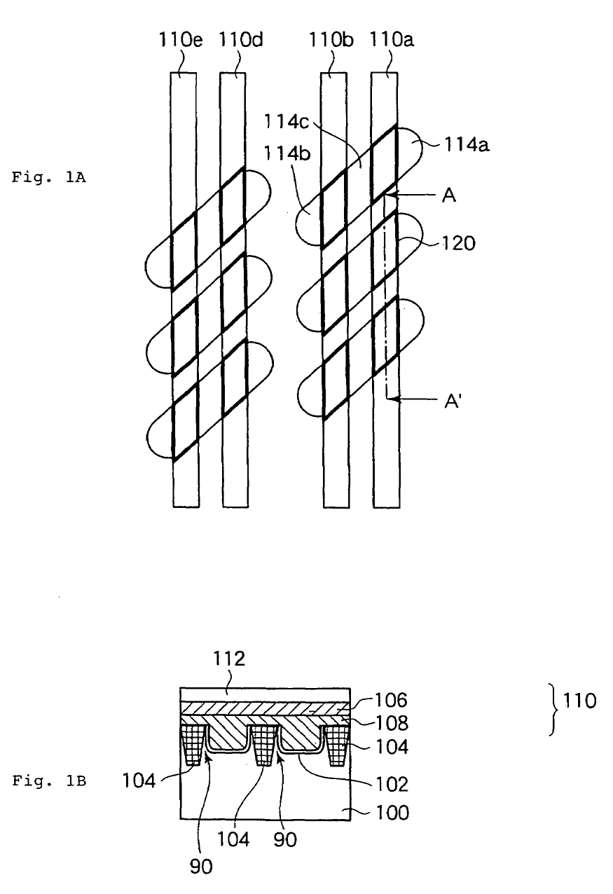

A doped polysilicon film is next buried in gate trenches 60 as in the first working example, the upper surface of the buried film is planarized, and a metal film and silicon nitride film (Si₃N₄ film) are formed over this planarized surface. PR (photoresist) having the gate electrode pattern shown in FIG. 1A is next formed on the silicon nitride film by a lithography method. The gate electrode pattern over diffusion regions corresponds to the spaces of oxidation-resistant insulation mask 12 of FIG. 6A. Using the PR as a mask, the silicon nitride film is then etched to form a hard mask from the silicon nitride film, following which the PR is removed. Finally, the doped polysilicon film and conductive film, i.e., metal film, are subjected to etching from above the hard mask formed by the silicon nitride film to form gate electrodes.

During this metal film etching, the width of the hard mask formed by the silicon nitride film is greater by the dimension of the side walls than the width of gate trenches 60, and the doped polysilicon film in gate trenches 60 is therefore not subjected to etching. In contrast, when the width of gate trenches 60 is equivalent to or greater than the width of the hard mask formed by the silicon nitride film, the etching of the gate electrode pattern must be carried out as far as the doped polysilicon film buried within gate trenches 60, and etching of gates with high step becomes necessary.

In the present working example, processing of the gate electrodes can be carried out with greater stability than when the width of the gate electrode pattern is smaller than the width of gate trenches.

Finally, although the explanation of the above-described first and second working examples regarded the case of DRAM, the present invention is not limited to DRAM, and the present invention can be applied to electronic devices which has DRAM, or to semiconductor devices other than DRAM such as MOS semiconductor elements.

While preferred embodiments of the present invention have been described using specific terms, such description is for illustrative purposes only, and it is to be understood that changes and variations may be made without departing from the spirit or scope of the following claims.

What is claimed is:

1. A method of fabricating a semiconductor device, said semiconductor device having trench gates as gate electrodes of transistors; said method comprising the steps of:
forming on a substrate element isolation parts that enclose a plurality of active regions in which said transistors are formed, wherein profiles of said element isolation parts in a perpendicular direction with respect to a substrate surface are reverse-tapered shapes;
after forming said element isolation parts, forming an oxidation-resistant insulation mask that covers the regions of sources and drains of said transistors in said plurality of active regions;
subjecting said substrate to anisotropic etching from above said oxidation-resistant insulation mask to form trenches for said trench gates in said active regions;
removing a natural oxidation film that has formed on a substrate surface of said trenches;
after removing said natural oxidation film, carrying out an annealing process by performing a heat treatment in a hydrogen atmosphere;
after said annealing process, removing said oxidation-resistant insulation mask;
after removing said oxidation-resistant insulation mask, carrying out a cleaning process by cleaning with a mixture containing ammonium-hydrogen peroxide; and
after said cleaning process, forming a gate oxide film on a substrate surface of said trenches by a thermal oxidation method.

2. A method of fabricating a semiconductor device according to claim 1, wherein, after said annealing process and before removing said oxidation-resistant insulation mask, forming an oxidation film on the substrate surface in said trenches by means of a thermal oxidation method, and further, removing said oxidation film that has been formed on the substrate surface in said trenches.

3. A method of fabricating a semiconductor device according to claim 1, wherein:
said oxidation-resistant insulation mask is a line pattern;
after forming said oxidation-resistant insulation mask and before carrying out said anisotropic etching, forming side walls by a material of the same kind as the oxidation-resistant insulation mask on the side walls of the oxidation-resistant insulation mask;
after forming said gate oxidation film, burying said trenches, and moreover, forming a conductive film having an upper surface that is higher than a surface of said substrate;
forming a gate electrode mask on said conductive film, said gate electrode mask having openings at positions of said line pattern; and
subjecting said conductive film to etching from above said gate electrode mask.

4. A method of fabricating a semiconductor device according to claim 2, wherein:
said oxidation-resistant insulation mask is a line pattern;
after forming said oxidation-resistant insulation mask and before carrying out said anisotropic etching, forming side walls by a material of the same kind as the oxidation-resistant insulation mask on the side walls of the oxidation-resistant insulation mask;
after forming said gate oxidation film, burying said trenches, and moreover, forming a conductive film having an upper surface that is higher than a surface of said substrate;
forming a gate electrode mask on said conductive film, said gate electrode mask having openings at positions of said line pattern; and
subjecting said conductive film to etching from above said gate electrode mask.

5. A method of fabricating a semiconductor device according to claim 1, wherein, as the conditions of said annealing process, the pressure is 30 Torr or less, and the temperature is at least 750° C. but not greater than 900° C.

6. A method of fabricating a semiconductor device according to claim 2, wherein, as the conditions of said annealing process, the pressure is 30 Torr or less, and the temperature is at least 750° C. but not greater than 900° C.

7. A method of fabricating a semiconductor device according to claim 3, wherein, as the conditions of said annealing process, the pressure is 30 Torr or less, and the temperature is at least 750° C. but not greater than 900° C.

8. A method of fabricating a semiconductor device according to claim 4, wherein, as the conditions of said annealing process, the pressure is 30 Torr or less, and the temperature is at least 750° C. but not greater than 900° C.

9. A method of fabricating a semiconductor device according to claim 1, wherein said annealing process is carried out by a Rapid Thermal Annealer.

10. A method of fabricating a semiconductor device according to claim 2, wherein said annealing process is carried out by a Rapid Thermal Annealer.

11. A method of fabricating a semiconductor device according to claim 3, wherein said annealing process is carried out by a Rapid Thermal Annealer.

12. A method of fabricating a semiconductor device according to claim 4, wherein said annealing process is carried out by a Rapid Thermal Annealer.

13. A method of fabricating a semiconductor device according to claim 1, wherein a material of said oxidation-resistant insulation mask is a silicon nitride film or a SiCN film.

14. A method of fabricating a semiconductor device according to claim 2, wherein a material of said oxidation-resistant insulation mask is a silicon nitride film or a SiCN film.

15. A method of fabricating a semiconductor device according to claim 3, wherein a material of said oxidation-resistant insulation mask is a silicon nitride film or a SiCN film.

16. A method of fabricating a semiconductor device according to claim 4, wherein a material of said oxidation-resistant insulation mask is a silicon nitride film or a SiCN film.
